(19) United States
(12) Patent Application Publication
(10) Pub. No.: US 2020/0371130 A1
(43) Pub. Date: Nov. 26, 2020

(54) INERTIAL SENSOR

(71) Applicant: PANASONIC INTELLECTUAL PROPERTY MANAGEMENT CO., LTD., Osaka (JP)

(72) Inventors: Takahiro SHINOHARA, Hyogo (JP); Kazuo GODA, Osaka (JP)

(21) Appl. No.: 16/958,838

(22) PCT Filed: Feb. 8, 2019
(86) PCT No.: PCT/JP2019/004610

§ 371 Date: Jun. 29, 2020

(30) Foreign Application Priority Data
Feb. 19, 2018 (JP) 2018-026989

(51) Int. Cl. G01P 15/125; B81B 7/00; B81C 1/00; G01P 1/00

(52) U.S. Cl. CPC G01P 15/125; B81B 7/0006; B81C 1/00547; B81B 2207/096; B81B 2201/0235; B81B 2201/0242; B81B 2207/098; G01P 1/00

(57) ABSTRACT

An inertial sensor according to the present disclosure includes a sensor element having a multilayer structure in which a first substrate, a second substrate, and a sensor substrate are stacked one on top of another. The first substrate includes a substrate body, a first interconnect, an electrode layer, and a silicon member. The first interconnect is provided inside the substrate body. The electrode layer is provided for the substrate body and electrically connected to the first interconnect. The silicon member is provided at an end of the substrate body. The silicon member has, in a cross-sectional view, a curved portion and a linear portion connected to the curved portion. The electrode layer is provided to cover the curved portion and the linear portion.

### TECHNICAL FIELD

The present disclosure generally relates to an inertial sensor for use to control vehicles, for example.

### BACKGROUND ART

A wiring glass substrate for use to extend wiring using a glass substrate in which wiring is embedded and a sensor including such a wiring glass substrate are known in the art.

For example, Patent Literature 1 is known as a prior art document disclosing such a structure.

However, the known structure allows the wiring to be extended electrically only from the upper surface of the wiring glass substrate, thus restricting the arrangement direction of the sensor.

### CITATION LIST

### Patent Literature

Patent Literature 1: JP 2014-131830 A

### SUMMARY OF INVENTION

It is therefore an object of the present disclosure to provide an inertial sensor with the ability to increase the degree of freedom on the arrangement direction of the sensor.

To achieve this object, an inertial sensor according to an aspect of the present disclosure includes a sensor element having a multilayer structure in which a first substrate, a second substrate, and a sensor substrate are stacked one on top of another. The first substrate includes a substrate body, a first interconnect, an electrode layer, and a silicon member. The first interconnect is provided inside the substrate body. The electrode layer is provided for the substrate body and electrically connected to the first interconnect. The silicon member is provided at an end of the substrate body. The silicon member has, in a cross-sectional view, a curved portion and a linear portion connected to the curved portion. The electrode layer is provided to cover the curved portion and the linear portion.

An inertial sensor according to another aspect of the present disclosure includes a sensor element having a multilayer structure in which a first substrate, a second substrate, and a sensor substrate are stacked one on top of another. The first substrate has a recess at one end thereof. The recess has a first curved surface and a second curved surface connected to the first curved surface. The first curved surface is a cylindrical curved surface. The second curved surface is a curved surface, of which an aperture increases as distance from the first curved surface increases. An electrode layer is provided to cover the first curved surface and the second curved surface.

### BRIEF DESCRIPTION OF DRAWINGS

FIG. 1 is a perspective view illustrating an internal configuration for an acceleration sensor according to a first embodiment;

FIG. 2 is a top view of the acceleration sensor;

FIG. 3 is an exploded perspective view illustrating a schematic configuration for an acceleration sensor element included in the acceleration sensor;

FIG. 4A is a top view of a first substrate included in the acceleration sensor element;

FIG. 4B is a front view of the first substrate;

FIG. 5A is a top view of a sensor substrate included in the acceleration sensor element;

FIG. 5B is a front view of the sensor substrate;

FIG. 6A is a top view of a second substrate included in the acceleration sensor element;

FIG. 6B is a front view of the second substrate;

FIGS. 7A and 7B illustrate the appearance of the acceleration sensor element that has been mounted:

FIGS. 8A and 8B illustrate the appearance of an acceleration sensor element included in an acceleration sensor according to a second embodiment after the acceleration sensor element has been mounted;

FIG. 9A is an enlarged view of a part shown in FIG. 8A;

FIG. 9B is a view of the part shown in FIG. 8A when viewed in a direction μl;

FIG. 10A illustrates the process step of etching a silicon member by non-Bosch process:

FIG. 10B illustrates the silicon member at a point in time when the etching process shown in FIG. 8A is finished; and

FIG. 10C is an enlarged view of a part indicated by the dashed rectangle R1 in FIG. 10B.

### DESCRIPTION OF EMBODIMENTS

Embodiments of the present disclosure will be described with reference to the accompanying drawings. Note that members shown on multiple drawings and having the same function are designated by the same reference sign.

### First Embodiment

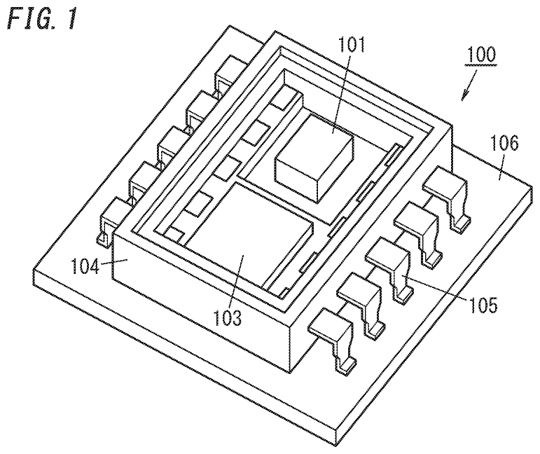

A schematic configuration for an acceleration sensor 100 according to an exemplary embodiment will be described with reference to FIG. 1.

In the following description of this exemplary embodiment, an acceleration sensor for detecting the acceleration will be described as an example of an inertial sensor.

FIG. 1 is a perspective view illustrating an internal configuration for the acceleration sensor 100.

As shown in FIG. 1, a package substrate 104 is mounted on an external substrate 106. In FIG. 1, a lid to close the opening of the package is not shown for the sake of simplicity.

On the package substrate 104, assembled are an acceleration sensor element 101 and a detector circuit 103 for detecting a physical quantity by performing various types of arithmetic operations based on the output of the acceleration sensor element 101.

A plurality of lead terminals 105 are extended from the package substrate 104. The lead terminals 105 extended from the package substrate 104 are connected to the external substrate 106.

The acceleration sensor 100 is a capacitive acceleration sensor. The acceleration sensor 100 may be manufactured by microelectromechanical systems (MEMS) technologies.

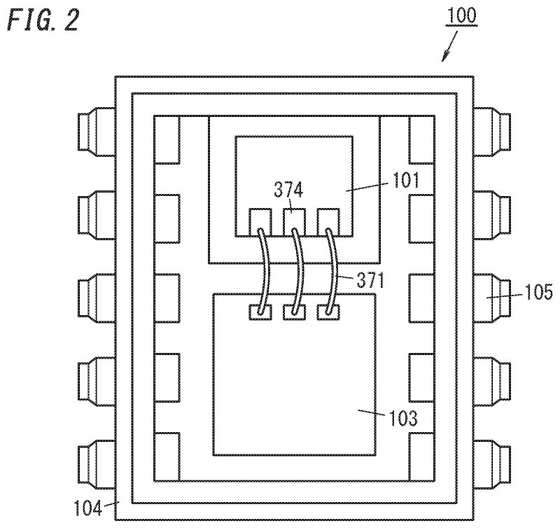

FIG. 2 is atop view of the acceleration sensor 100.

The acceleration sensor element 101 is arranged such that its electrode layer 374 is exposed in a top view as shown in FIG. 2. Metallic wires 371 are connected to the electrode layer 374. The electrode layer 374 will be described in detail later.

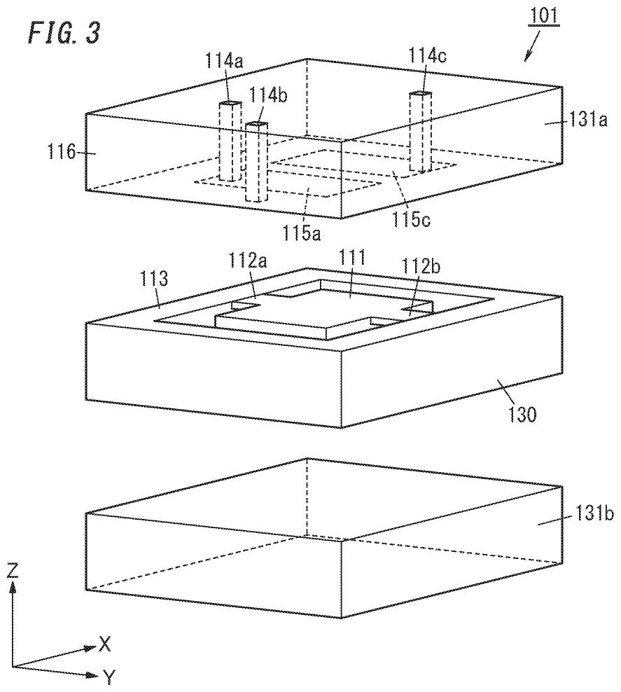

FIG. 3 is an exploded perspective view illustrating a schematic configuration for the acceleration sensor element 101. Note that illustration of a part of the configuration of the acceleration sensor element 101 may be omitted in FIG. 3.

As shown in FIG. 3, the acceleration sensor element 101 has a structure in which a sensor substrate 130, a substrate 131a serving as a first substrate, and another substrate 131b serving as a second substrate are stacked one on top of another. Stated otherwise, the acceleration sensor element 101 has a structure in which the sensor substrate 130 is sandwiched between the substrates 131a. 131b. In the following description, the direction in which the sensor substrate 130 and the substrates 131a, 131b are stacked one on top of another will be hereinafter referred to as a “stacking direction.” That is to say, in FIG. 3, the stacking direction corresponds to a Z-axis direction.

The sensor substrate 130 includes a plumb portion 111 for detecting acceleration in an X-axis direction, and beam portions 112a, 112b for connecting the plumb portion 111 to a supporting portion 113. A semiconductor substrate such as an SOI substrate may be used as the sensor substrate 130.

The substrate 131a includes a substrate body 116, fixed electrodes 115a, 115c, and feedthrough connectors 114a, 114b, 114c for outputting electrical signals from the fixed electrodes 115a, 115c to an external device. A substrate including glass may be used as the substrate body 116.

The respective fixed electrodes 115a, 115c may be formed out of a thin metallic film such as an Al—Sl film.

The substrate 131b is arranged on the package substrate 104. A substrate including glass may be used as the substrate 131b.

The feedthrough connectors 114a, 114b, 114c are provided to run through the substrate 131a, and are electrically connected to either the fixed electrodes 115a, 115c or the acceleration sensor element 101. Although not shown in FIG. 3, the respective end faces of the feedthrough connectors 114a, 114b, 114c are covered with an electrode layer 374 to be connected to the metallic wires 371. In the following description, when there is no need to distinguish these feedthrough connectors 114a, 114b, 114c from each other, these feedthrough connectors 114a, 114b, 114c will be hereinafter collectively referred to as “feedthrough connectors 114.”

In this acceleration sensor element 101, a capacitor, of which the capacitance varies according to the acceleration, is formed between the plumb portion 111 and the fixed electrodes 115a, 115c. More specifically, application of acceleration to the plumb portion 11l causes the beam portions 112a, 112b to be distorted and the plumb portion 111 to be displaced, thus varying the area and interval of respective facing regions of the fixed electrodes 115a, 115c and the plumb portion 111 and eventually causing a variation in the capacitance of the capacitor. Based on this variation in capacitance, the acceleration sensor element 101 is able to detect the acceleration.

In the foregoing description of this exemplary embodiment, the inertial sensor is implemented as the acceleration sensor 100 including the acceleration sensor element 101 for detecting acceleration in the X-axis direction. However, this is only an example and should not be construed as limiting. Alternatively, the inertial sensor may also be an acceleration sensor including an acceleration sensor element for detecting acceleration in a Y-axis direction or the Z-axis direction. Still alternatively, the inertial sensor may also be implemented as an angular velocity sensor including an angular velocity sensor element for detecting an angular velocity around the X-, Y-, and/or Z-axis.

The acceleration sensor element 101 is connected to the detector circuit 103 via the metallic wires 371 (see FIG. 2).

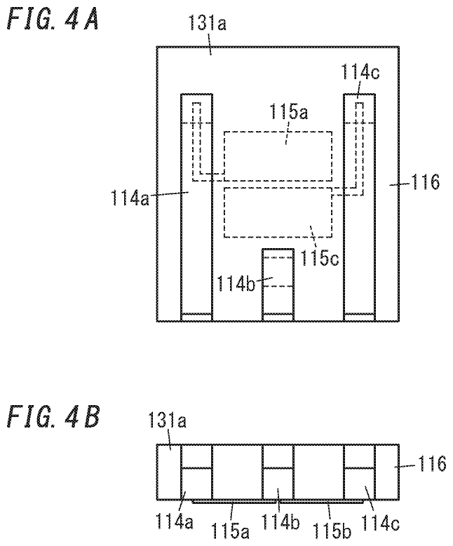

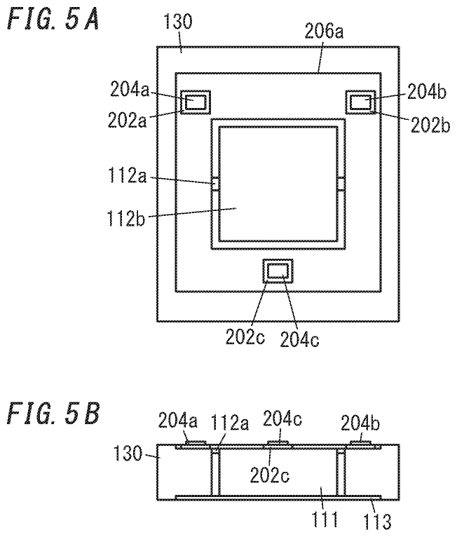

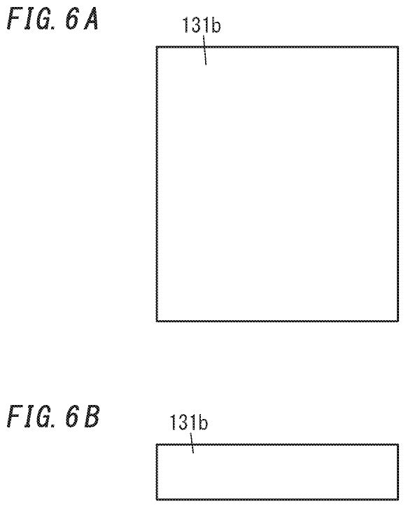

FIG. 4A is a top view of the substrate 131a included in the acceleration sensor element 101. FIG. 4B is a front view of the substrate 131a. FIG. 5A is a top view of the sensor substrate 130 included in the acceleration sensor element 101. FIG. 5B is a front view of the sensor substrate 130. FIG. 6A is a top view of the substrate 131b included in the acceleration sensor element 101. FIG. 6B is a front view of the substrate 131b.

The fixed electrode 115a provided on one surface, which is to be bonded onto the sensor substrate 130, of the substrate body 116 is electrically bonded to the feedthrough connector 114a. The fixed electrode 115c provided on that surface, which is to be bonded onto the sensor substrate 130, of the substrate body 116 is electrically bonded to the feedthrough connector 114c. A first electrode 204a and a second electrode 204b are respectively provided right over insulating layers 202a and 202b in a recess 206a of the sensor substrate 130.

The respective surfaces of the first electrode 204a and the second electrode 204b are suitably slightly raised over the surface of the sensor substrate 130. Their protrusion height is suitably approximately 1.0 μm or less. This allows, when the sensor substrate 130 and the substrate 131a are bonded together, the first electrode 204a and the second electrode 204b to be press-fitted with more reliability, thus increasing the reliability of connection between the sensor substrate 130 and the substrate 131a.

An (island of) insulating layer 202c is an islanded portion provided in the recess 206a of the sensor substrate 130 and made of the same material as the sensor substrate 130. A third electrode 204c provided right over the insulating layer 202c will be connected to the feedthrough connector 114b after the sensor substrate 130 and the substrate 131a are bonded together. That is to say, the feedthrough connector 114b supplies the potential of the sensor substrate 130.

The surface of the third electrode 204c is suitably slightly raised over the surface of the sensor substrate 130. Its protrusion height is suitably approximately 1.0 μm or less. This allows, when the sensor substrate 130 and the substrate 131a are bonded together, the third electrode 204c to be press-fitted, thus increasing the reliability of electrical connection.

In this case, the first electrode 204a, the second electrode 204b, and the third electrode 204c are arranged so as to form a triangular pattern in a top view. This increases the degree of symmetry of the sensor substrate 130, thus improving the temperature characteristic of the acceleration sensor element 101.

The insulating layers 202a-202c and the first to third electrodes 204a-204c are arranged inside the recess 206a. An outer peripheral portion, surrounding the recess 206a, of the sensor substrate 130 is connected to the substrate 131a.

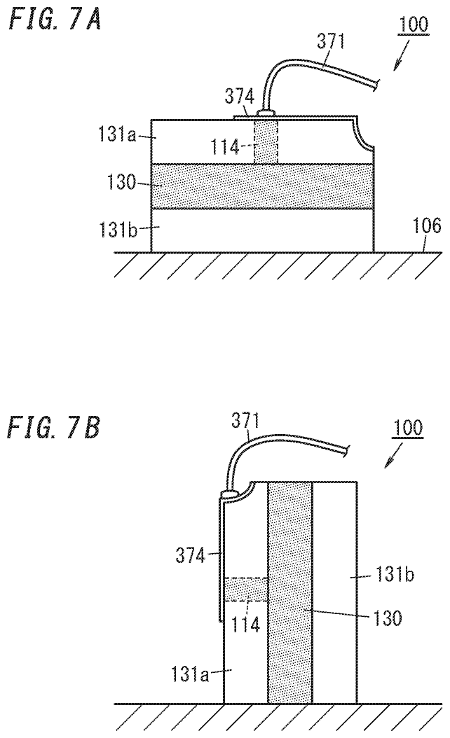

FIGS. 7A and 7B illustrate the appearance of the acceleration sensor element 101 that has been mounted. FIG. 7A illustrates the appearance of the acceleration sensor element 101 mounted vertically, while FIG. 7B illustrates the appearance of the acceleration sensor element 101 mounted transversally.

As shown in FIGS. 7A and 7B, no matter whether the acceleration sensor element 101 is mounted vertically or transversally with respect to the external substrate 106, the acceleration sensor element 101 allows the metallic wires 371 to be extended. This facilitates outputting an electrical signal to an external device, thus achieving the advantage of increasing the degree of freedom on the arrangement direction of the sensor.

### Second Embodiment

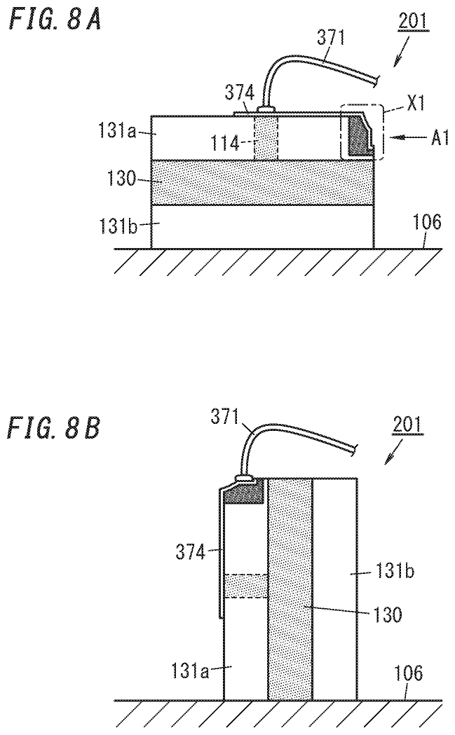

Next, an acceleration sensor 100 according to a second exemplary embodiment will be described with reference to FIGS. 8A-10C.

FIGS. 8A and 8B illustrate the appearance of an acceleration sensor element 201 according to this embodiment that has been mounted. FIG. 8A illustrates the appearance of the acceleration sensor element 201 mounted vertically, while FIG. 8B illustrates the appearance of the acceleration sensor element 201 mounted transversally.

As shown in FIGS. 8A and 8B, no matter whether the acceleration sensor element 201 is mounted vertically or transversally with respect to the external substrate 106, the acceleration sensor element 201 allows the metallic wires 371 to be extended. This facilitates outputting an electrical signal to an external device, thus achieving the advantage of increasing the degree of freedom on the arrangement direction of the sensor.

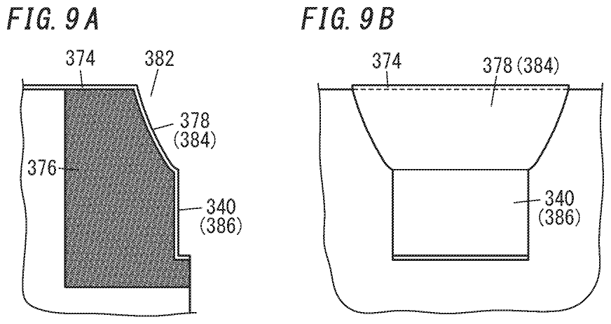

FIG. 9A is an enlarged view of a part XI indicated by the one-dot rectangle in FIG. 8A, and FIG. 9B is a view of the part XI shown in FIG. 8A when viewed in a direction μl.

The substrate 131a included in the acceleration sensor element 201 includes a silicon member 376.

The silicon member 376 is provided at one end (e.g., the right end in FIG. 8A) of the substrate 131a and has an L-cross section when viewed in a direction (i.e., the direction coming out of the paper of FIG. 8A) intersecting with the direction (i.e., the upward/downward direction in FIG. 8A) in which the substrates 131a, 131b and the sensor substrate 130 are stacked one on top of another. Furthermore, the silicon member 376 has a curved portion 378 and a linear portion 340 connected to the curved portion 378. As shown in FIG. 9A, the electrode layer 374 is provided to cover the curved portion 378 and the linear portion 340.

The acceleration sensor element 201 may also be described as follows.

The substrate 131a has a recess 382 provided at one end (e.g., the right end in FIG. 8A) of the substrate body 116. The recess 382 includes a first curved surface 386 and a second curved surface 384. The first curved surface 386 and the second curved surface 384 are arranged one on top of the other in the direction in which the sensor substrate 130 and the substrates 131a, 131b are stacked one on top of another. The first curved surface 386 is a cylindrical curved surface aligned with the stacking direction. As used herein, the “cylindrical curved surface” refers to a part (e.g., a half) of the circumferential surface of a cylinder. The second curved surface 384 is a curved surface, of which the aperture increases as the distance from the first curved surface 386 increases. The second curved surface 384 may be a funnel-shaped surface, for example. As used herein, the “funnel-shaped surface” refers to a part (e.g., a half) of the circumferential surface of the funnel.

The process of making the silicon member 376 of the acceleration sensor element 201 may include an etching process step using a non-Bosch process and an etching process step using a Bosch process. The etching process step using the non-Bosch process includes etching the silicon member 376 embedded in the substrate 131a. This allows the curved portion 378 of the silicon member 376 (i.e., the second curved surface 384 of the recess 382) to be formed.

The etching process step using the Bosch process includes further etching the silicon member 376 that has been subjected to the etching process step using the non-Bosch process. This allows the curved portion 378 of the silicon member 376 (i.e., the second curved surface 384) to be formed. In addition, this also allows the linear portion 340 of the silicon member 376 (i.e., the first curved surface 386 of the recess 382) to be formed.

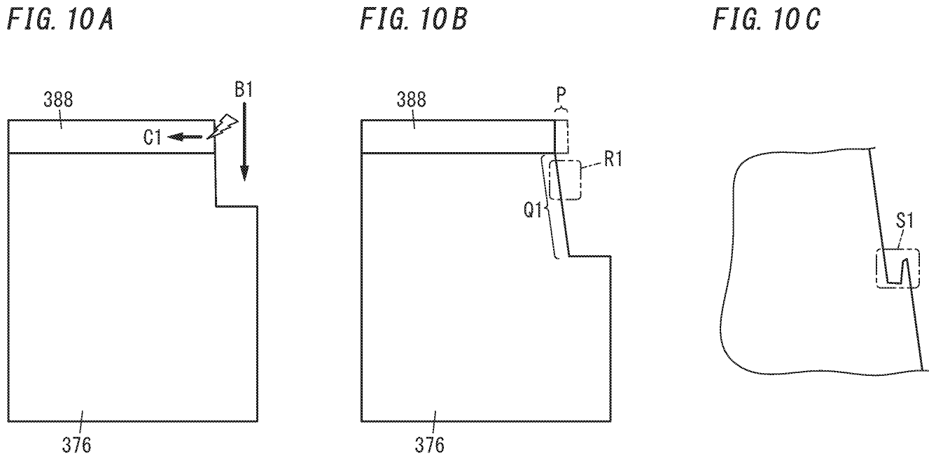

Optionally, when the silicon member 376 is formed, the etching process step using the non-Bosch process may be omitted. The process of making the silicon member 376 when the etching process step using the non-Bosch process is omitted will be described with reference to FIGS. 10A-10C. FIG. 10A illustrates the process step of etching, by the Bosch process, the silicon member 376 embedded in the substrate 131a. FIG. 10B illustrates the silicon member 376 at a point in time when the etching process shown in FIG. 10A is finished. FIG. 10C is an enlarged view of a part indicated by the one-dot rectangle R1 in FIG. 10B.

As shown in FIG. 10A, while the silicon member 376 is being etched by the etching process step using the Bosch process (i.e., while the silicon member 376 is being etched in the direction indicated by the arrow B1) a photoresist may also be etched and retracted (i.e., the photoresist 388 may be retracted in the direction indicated by the arrow C1). When this happens, a side surface of the silicon member 376 (i.e., a portion indicated by Q1 in FIG. 10B) is etched by the retracted part of the photoresist 388 (i.e., the region surrounded with the dashed rectangle P1 in FIG. 10B). In that case, the side surface of the silicon member 376 comes to have an overly depressed portion (i.e., the region surrounded with the one-dot rectangle S1 in FIG. 10C). With such an overly depressed portion present, when the electrode layer 374 is deposited thereon by sputtering, for example, the electrode layer 374 will rupture at the overly depressed portion. As already described with reference to FIGS. 8A and 8B, the electrode layer 374 needs to be electrically connected to the feedthrough connectors 114a, 114b, 114c. However, particularly when the structure shown in FIG. 8B is adopted, causing the electrode layer 374 to rupture at the overly depressed portion prevents the metallic wires 371 from being electrically connected to the feedthrough connectors 114a, 114b, 114c, thus making the structure unable to function as the acceleration sensor 100. In contrast, performing the etching process step using the non-Bosch process to provide an under-cut portion for the silicon member 376 before performing the etching process step using the Bosch process reduces the chances of the side surface of the silicon member 376 being overly depressed.

This reduces the chances of the electrode layer 374 rupturing.

It is known that the linear portion 340 formed by the etching process step using the Bosch process (or the first curved surface 386) comes to have a so-called “scallop” shape, which is a wavy shape as seen on the surface of a scallop. Forming the electrode layer 374 on the scallop causes a significant decrease in the degree of close contact of the electrode. This may cause metallic wires provided on the electrode layer 374 by wire bonding to peel off. That is why the linear portion 340 (i.e., the first curved surface 386) is suitably subjected to a TMAH process to increase the degree of surface planarity after having been subjected to the etching process step using the Bosch process. This increases the degree of close contact of the electrode. Consequently, this reduces the chances of the metallic wires provided on the electrode layer 374 by wire bonding peeling off.

### Resume

As can be seen from the foregoing description, an inertial sensor (100) according to a first aspect includes a sensor element (101; 201) having a multilayer structure in which a first substrate (131a), a second substrate (131b), and a sensor substrate (130) are stacked one on top of another. The first substrate (131a) includes: a substrate body (116); a first interconnect (114) provided inside the substrate body (116); an electrode layer (374) provided for the substrate body (116) and electrically connected to the first interconnect (114); and a silicon member (376) provided at an end of the substrate body (116). The silicon member (376) has, in a cross-sectional view, a curved portion (378) and a linear portion (340) connected to the curved portion (378). The electrode layer (374) is provided to cover the curved portion (378) and the linear portion (340).

According to this aspect, the electrode layer (374) is provided to cover the curved portion (378) and the linear portion (340), thus increasing the degree of freedom on an extension position of a metallic wire (371), and eventually increasing the degree of freedom on the arrangement direction of the sensor.

In an inertial sensor (100) according to a second aspect, which may be implemented in conjunction with the first aspect, the curved portion (378) and the linear portion (340) are arranged one on top of the other in a direction in which the first substrate (131a), the second substrate (131b), and the sensor substrate (130) are stacked one on top of another (e.g., in a Z-axis direction).

According to this aspect, the electrode layer (374) is provided to cover the curved portion (378) and the linear portion (340), thus increasing the degree of freedom on an extension position of a metallic wire (371), and eventually increasing the degree of freedom on the arrangement direction of the sensor.

In an inertial sensor (100) according to a third aspect, which may be implemented in conjunction with the first or second aspect, the silicon member (376) has a part including the curved portion (378) and the linear portion (340) and having an L-cross section.

According to this aspect, the electrode layer (374) is provided to cover the curved portion (378) and the linear portion (340), thus increasing the degree of freedom on an extension position of a metallic wire (371), and eventually increasing the degree of freedom on the arrangement direction of the sensor.

An inertial sensor (100) according to a fourth aspect includes a sensor element (101; 201) having a multilayer structure in which a first substrate (131a), a second substrate (131b) and a sensor substrate (130) are stacked one on top of another. The first substrate (131a) has a recess (382) atone end thereof. The recess (382) has a first curved surface (386) and a second curved surface (384) connected to the first curved surface (386). The first curved surface (386) is a cylindrical curved surface. The second curved surface (384) is a curved surface, of which an aperture increases as distance from the first curved surface (386) increases. In the inertial sensor (100), an electrode layer (374) is provided to cover the first curved surface (386) and the second curved surface (384).

According to this aspect, the electrode layer (374) is arranged to cover the first curved surface (386) and the second curved surface (384), thus increasing the degree of freedom on an extension position of a metallic wire (371), and eventually increasing the degree of freedom on the arrangement direction of the sensor.

In an inertial sensor (100) according to a fifth aspect, which may be implemented in conjunction with the fourth aspect, the first curved surface (386) and the second curved surface (384) are arranged one on top of the other in a direction in which the first substrate (131a), the second substrate (131b), and the sensor substrate (130) are stacked one on top of another.

According to this aspect, the electrode layer (374) is arranged to cover the first curved surface (386) and the second curved surface (384), thus increasing the degree of freedom on an extension position of a metallic wire (371), and eventually increasing the degree of freedom on the arrangement direction of the sensor.

In an inertial sensor (100) according to a sixth aspect, which may be implemented in conjunction with the fourth or fifth aspect, the second curved surface (384) is a funnel-shaped surface.

According to this aspect, the electrode layer (374) is arranged to cover the first curved surface (386) and the second curved surface (384), thus increasing the degree of freedom on an extension position of a metallic wire (371), and eventually increasing the degree of freedom on the arrangement direction of the sensor.

Note that constituent elements according to the second, third, fifth, and sixth aspects are not essential constituent elements for the inertial sensor (100) but may be omitted as appropriate.

### INDUSTRIAL APPLICABILITY

The present disclosure is effectively applicable to a wiring glass substrate and an inertial sensor including such a glass substrate.

### REFERENCE SIGNS LIST

100 Acceleration Sensor (Inertial Sensor)
101, 201 Acceleration Sensor Element
104 Package Substrate
105 Lead Terminal
106 External Substrate
111 Plumb Portion
113 Supporting Portion
112a, 112b Beam Portion
114, 114a, 114b, 114c Feedthrough Connector (First Interconnect)
115a, 115c Fixed Electrode
116 Substrate Body
130 Sensor Substrate
131a Substrate (First Substrate)
131b Substrate (Second Substrate)
202a. 202b, 202c Insulating Layer
204a First Electrode
204b Second Electrode
204c Third Electrode
206a Recess
371 Metallic Wire
374 Electrode Layer
376 Silicon Member
378 Curved Portion
340 Linear Portion
382 Recess
384 Second Curved Surface
386 First Curved Surface
388 Photoresist

1. An inertial sensor comprising a sensor element having a multilayer structure in which a first substrate, a second substrate, and a sensor substrate are stacked one on top of another,
the first substrate including:
a substrate body;
a first interconnect provided inside the substrate body;
an electrode layer provided for the substrate body and electrically connected to the first interconnect; and
a silicon member provided at an end of the substrate body,
the silicon member having, in a cross-sectional view, a curved portion and a linear portion connected to the curved portion,
the electrode layer being provided to cover the curved portion and the linear portion.

2. The inertial sensor of claim 1, wherein
the curved portion and the linear portion are arranged one on top of the other in a direction in which the first substrate, the second substrate, and the sensor substrate are stacked one on top of another.

3. The inertial sensor of claim 1, wherein
the silicon member has a part including the curved portion and the linear portion and having an L-cross section.

4. An inertial sensor comprising a sensor element having a multilayer structure in which a first substrate, a second substrate, and a sensor substrate are stacked one on top of another,
the first substrate having a recess at one end thereof,
the recess having a first curved surface and a second curved surface connected to the first curved surface,
the first curved surface being a cylindrical curved surface,
the second curved surface being a curved surface, of which an aperture increases as distance from the first curved surface increases,
an electrode layer being provided to cover the first curved surface and the second curved surface.

5. The inertial sensor of claim 4, wherein
the first curved surface and the second curved surface are arranged one on top of the other in a direction in which the first substrate, the second substrate, and the sensor substrate are stacked one on top of another.

6. The inertial sensor of claim 4, wherein
the second curved surface is a funnel-shaped surface.

7. The inertial sensor of claim 2, wherein
the silicon member has a part including the curved portion and the linear portion and having an L-cross section.

8. The inertial sensor of claim 5, wherein
the second curved surface is a funnel-shaped surface.
